(19) United States
(12) Patent Application Publication
(10) Pub. No.: US 2026/0119771 A1
(43) Pub. Date: Apr. 30, 2026

(54) Method for Transistor Layout Design Using 3D Model Representation in Latent Space

(71) Applicant: GenChip.AI Inc., Sunnyvale, CA (US)

(72) Inventors: Sreekar Bathula, San Jose, CA (US); Eric Panning, Portland, OR (US)

(21) Appl. No.: 19/376,725

(22) Filed: Oct. 31, 2025

Related U.S. Application Data
(60) Provisional application No. 63/714,773, filed on Oct. 31, 2024.
(60) Provisional application No. 63/714,754, filed on Oct. 31, 2024.
(60) Provisional application No. 63/714,761, filed on Oct. 31, 2024.
(60) Provisional application No. 63/714,793, filed on Oct. 31, 2024.
(60) Provisional application No. 63/714,797, filed on Oct. 31, 2024.
(60) Provisional application No. 63/714,796, filed on Oct. 31, 2024.

(51) Int. Cl. G06F 30/392; G06N 3/042; G06N 3/0475; G06N 3/092

(52) U.S. Cl. CPC G06F 30/392; G06N 3/042; G06N 3/0475; G06N 3/092

(57) ABSTRACT

A method for automating semiconductor design is disclosed, which includes optimizing integrated circuit layouts using latent space models and reinforcement learning. The described method enables efficient physical layout design by generating embeddings from a process design kit, placing them in a latent space representation model and producing candidate physical layouts. Resistance-capacitance values are extracted, and reward values are assigned to guide the reinforcement learning model. This process iteratively refines the generative layout synthesis model, enhancing design rule checking scores and efficiency. Primary application is in electronic design automation (EDA) for integrated circuits, improving design accuracy and reducing processing time.

### CROSS-REFERENCE TO RELATED APPLICATIONS

This application claims the benefit of and priority to U.S. Provisional Patent Application Ser. No. 63/714,754 entitled “Method for Estimating Parasitic Capacitance Using Spatial Localization,” 63/714,761 entitled “Method and System for Estimating Parasitic Capacitance Using Localized Weighting and Federated Learning Model,” 63/714,793 entitled “Method for Transistor Order Placement Using Graph Neural Network Recursive Model,” 63/714,797 entitled “Method for Transistor Layout Generation Using Graph Neural Network Recursive Model,” 63/714,796 entitled “Method for Transistor Layout Design Checking Using Reinforcement Learning,” and 63/714,773 entitled “Method For Transistor Layout Design Using 3D Model Representation in Latent Space,” all of which were filed on Oct. 31, 2024 and which applications are expressly incorporated herein by reference in their entirety.

### BACKGROUND OF THE INVENTION

The present disclosure generally relates to electronic design automation for the design and manufacture of integrated circuits and microelectronics.

Electronic design automation (EDA) includes software tools for designing electronic systems such as integrated circuits. With semiconductor chips having billions of components or more, computer-aided tools are essential for logical design, physical design, and manufacturing processes. Integrated circuit design includes many steps, typically beginning with a system specification. Following system specification, several logical design steps can be completed based on that specification including register transfer level design, functional verification, timing simulation, and Netlist generation. After logical design, physical design steps can be executed to generate a physical layout of the integrated circuit. There are many physical design steps including partitioning, floor planning, placement, clock tree synthesis, and signal routing, among others. After a physical layout is verified, then an integrated circuit can be fabricated using the physical layout generated from EDA tools.

EDA tools are helpful to optimize the production process for semiconductor devices, such as integrated circuits. Such optimization involves designing semiconductor layouts and evaluating properties of the designs. Important properties assessed include resistance and capacitance, which are instrumental in deriving estimates for Power, Performance, Area, and Cost (PPAC) of a semiconductor device. The accurate estimation of these properties can significantly influence cost savings. Various tools are employed in this process to perform detailed 3D assessments of the designs, enabling precise point-to-point calculations of resistance and capacitance. During the physical design process of an integrated circuit, a significant variable to generating an acceptable design that meets logical constraints and system specifications is parasitic capacitance. Parasitic capacitance is the unwanted, yet unavoidable, capacitance that exists between conductive parts of an electronic circuit. Parasitic capacitance can cause the behavior of chip components to depart from ideal performance. The calculation of resistance and capacitance thus plays an important role in determining power and performance values.

Physical layout design for integrated circuits is often complicated, challenging, and time consuming. A given logical design can identify the logical circuits and transistors to be included in a particular design, but then identifying a physical placement layout of transistors—that meets device specifications—is challenging because of the millions or more different layouts possible, each with respective advantages and disadvantages.

### SUMMARY OF THE INVENTION

Maintaining continuous, accurate, and precise operation of semiconductor manufacturing tools is essential for maximizing device yield. These tools, however, often require extensive processing time due to the rigorous calculations needed to ensure devices are manufactured correctly. These calculations provide important feedback for refining initial device designs. Delays and yield losses can significantly decrease productivity and increase the depreciation costs of processing tools. Furthermore, these tools can impact the productivity of engineers and limit opportunities for optimizing designs.

Conventional tools that perform parasitic extraction (PEX) calculations take an initial layout as input, actuate the process to create the complete semiconductor device, and then calculate the resistance and capacitance values based on the process and design. These calculations are then analyzed, and a layout can be corrected. This iterative process continues until the desired value set is achieved. This iterative process is very time consuming, which can add significant costs and/or delays to circuit design.

Techniques herein provide methods and systems to improve electronic design accuracy and duration. Techniques include incorporating latent space models for optimizing physical layout of an integrated circuit using a reinforcement learning agent. An architecture of latent space and reinforcement learning enables identifying a best design or improved design that gets more reward according to a user's choice. The generation here uses 3D data of a semiconductor for a given layout and the availability of the parasitics. These 3D layouts are used as a ground truth of a model that generates embeddings of the 3D model and the same embeddings are used to generate the capacitance and resistance values corresponding to the given embedding. This embedding model is used in a reinforcement learning engine to determine the resistance and capacitance value and move in the latent space to determine an optimized or improved layout.

One general aspect herein includes a method for automating semiconductor design. The method can include receiving a process design kit that includes parameterized designs of standard cells. The method also includes generating, by a processing device, embeddings from the process design kit, the embeddings having parameter variations corresponding to the parameterized designs of the standard cells. The method also includes placing, by the processing device, the embeddings in a latent space representation model. The method also includes generating, by the processing device, candidate physical layouts of the standard cells from the latent space representation model using a generative layout synthesis model. The method also includes extracting, by the processing device, resistance-capacitance values of each candidate physical layout and assigning a reward value to each candidate physical layout based on the resistance-capacitance values. The method also includes updating, by the processing device, the generative layout synthesis model using assigned reward values such that the assigned reward values modify the generative layout synthesis model according to the reward values. Other embodiments of this aspect include corresponding computer systems, apparatus, and computer programs recorded on one or more computer storage devices, each configured to perform the actions of the methods.

### BRIEF DESCRIPTION OF DRAWINGS

This disclosure will be understood more fully from the detailed description below and from the accompanying figures of embodiments of the disclosure. The figures are used to facilitate understanding of embodiments of the disclosure and do not limit the scope of the disclosure to these specific embodiments. The figures are not necessarily drawn to scale.

FIG. 1 is a flow diagram of systems herein for automated layout design using latent space models.

FIG. 2 is a diagram of example subsystems used herein.

FIG. 3 is a conceptual representation for latent space models herein.

FIG. 4 is a flow chart of example methods disclosed herein.

FIG. 5 depicts a representative diagram of an example computer system in which embodiments of the present disclosure may operate.

### DETAILED DESCRIPTION

In the field of semiconductor design, particularly within Electronic Design Automation (EDA), the optimization of semiconductor device layouts is a valuable addition. EDA involves intricate calculations to ensure that the designs meet specific performance criteria, such as resistance and capacitance, which play a significant role in determining the Power, Performance, Area, and Cost (PPAC) of the devices. Conventional techniques for optimizing these layouts often rely on iterative processes that can be time-consuming and computationally intensive. These methods typically involve parasitic extraction (PEX) calculations, where the initial layout is used to simulate the complete semiconductor device, followed by resistance and capacitance calculations. The results are then analyzed to refine the layout, and this cycle continues until the desired specifications are met. Such iterative processes can lead to significant delays, impacting productivity and increasing the depreciation costs of manufacturing tools. Moreover, these methods often lack the flexibility to explore a wide range of design alternatives efficiently.

Existing technologies in semiconductor design encounter several challenges. The reliance on traditional PEX tools often leads to extended processing times due to the complexity of the calculations required. These tools can also restrict the ability of engineers to explore alternative design optimizations, as the feedback loop for refining designs is naturally slow. Additionally, the accuracy of these tools is of great importance, because any discrepancies in resistance and capacitance calculations can lead to suboptimal device performance, affecting yield and increasing costs. The demand for precise and efficient design processes is further intensified by the growing complexity of semiconductor devices, which require more sophisticated design and verification techniques. As the number of design rules and layout constraints increases, traditional methods struggle to scale effectively.

The present approach addresses these challenges by introducing a novel method for semiconductor design improvement. This method leverages the concept of latent space optimization, combined with a reinforcement learning (RL) framework, to enhance the efficiency and effectiveness of standard cell layout design processes. By using a latent space representation or latent space model, the system can navigate the high-dimensional design space more effectively, identifying optimal solutions that adhere to design rule checks (DRC) and layout-versus-schematic (LVS) requirements. The architecture allows for the generation of embeddings from 3D layout data, which are then used to predict resistance and capacitance values. These embeddings are derived from a trained autoencoder model that compresses the 3D layout into a lower-dimensional latent space while preserving key physical and electrical characteristics. This method significantly reduces the time required for design optimization, providing rapid feedback for layout refinement and enabling the exploration of a broader range of design possibilities. In particular, these techniques can be used to enhance the efficiency and effectiveness of semiconductor design processes with respect to standard cell layout design.

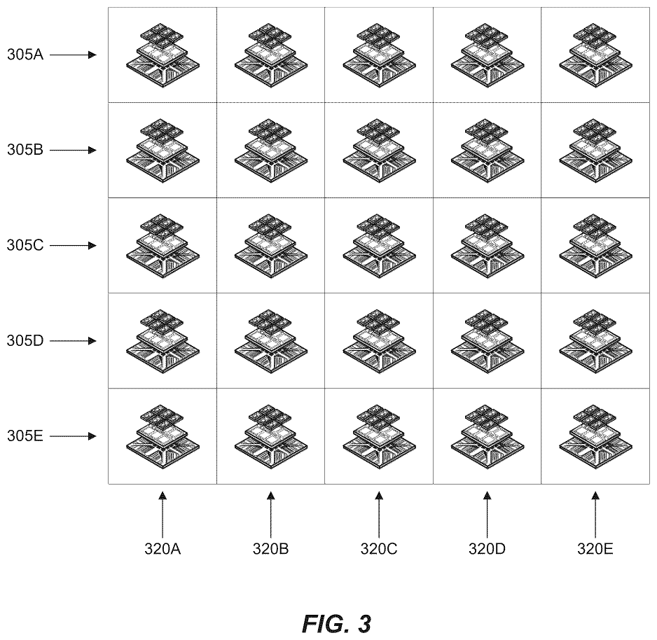

Embodiments include creating a latent space representation configured to obtain readable parameter variations of a PDK (process design kit). The PDK can be accessed from a PDK tech file, which contains technology-specific rules and constraints. A 3D layout input is passed through an autoencoder neural network to obtain compressed embeddings that represent readable parameters in or from the PDK technology. These embeddings are placed in a latent space representation configured to obtain an architecture representation that captures the essential layout features. The latent space enables efficient manipulation of layout parameters for optimization. An example representation is shown in FIG. 3.

FIG. 3 illustrates a conceptual table array for incremental changes in various standard cell parameters. For example, Rows 305A to 305E can represent different variables of a candidate physical design of an integrated circuit or standard cell. By way of a non-limiting example, Row 305A can identify layer width, Row 305B can identify layer gap, Row 305C can identify metal pitch, Row 305D can identify metal width, and Row 305E can identify metal material. Other parameters that can be included in the latent space model include via dimensions, contact resistance, dielectric thickness, and inter-layer spacing. The columns can then, for example, increment through various scales or dimensions. The degree of incrementation can be based on design tolerance, manufacturing constraints, or optimization objectives. For example, 320A can be 10 nanometers, 320B can be 20 nanometers, 320C can be 30 nanometers, 320D can be 40 nanometers, and 320E can be 50 nanometers. These increments allow the RL model to explore fine-grained variations in layout parameters.

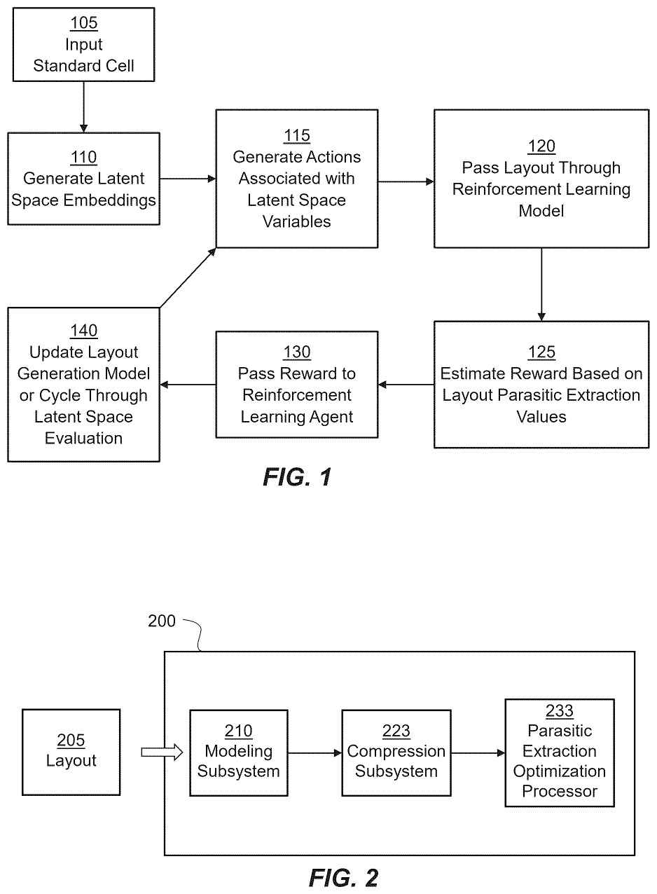

Accordingly, the system herein can create a latent space representation using available design data and incrementations thereof. This design data contains generated 3D layouts with process parameters as an input. Furthermore, the RL-based embedding fixing model can be configured to select actions from these embeddings by changing parameter values in a positive or negative direction, and with different degrees of change in the latent space to vary between parameters. The RL agent receives feedback based on DRC and LVS compliance, as well as predicted resistance and capacitance values, to guide the optimization process. This process makes the learning curve of the DRC engine optimized because the model is trained on the readable parameters, for significant improvement. Output from the model can be used in or with the PDK to generate optimized layouts for other cells too. This enables a scalable and adaptive design methodology that can generalize across different standard cell types and technology nodes. FIG. 1 illustrates an example process flow of techniques herein.

Referring now to FIG. 1, the system begins at step 105 with the input of one or more standard cells, typically sourced from a Process Design Kit (PDK). These standard cells are either pre-parameterized or parameterized by the system upon ingestion. Each standard cell includes logical and physical layout information, such as transistor-level schematics, pin configurations, and geometric constraints. This input forms the foundational dataset for subsequent latent space modeling. The standardization ensures consistency across design iterations and enables the system to perform structured exploration and optimization of layout configurations.

In step 110, the system generates latent space embeddings from the input standard cells. This involves transforming the design data into a compact, structured representation suitable for machine learning-based optimization. The embeddings capture variations in design parameters such as cell height, width, pin placement, and routing constraints. In some embodiments, a 3D layout representation is encoded using an autoencoder neural network to extract latent variables that preserve essential design features. These embeddings allow the system to navigate a high-dimensional design space efficiently, enabling scalable and automated layout synthesis.

In step 115, the system generates a set of actions associated with the latent space variables. These actions represent permissible transformations or perturbations in the latent space, such as shifting pin locations, resizing cells, or modifying routing paths. The action space is structured to align with physical design rules and constraints, enabling the system to explore feasible design alternatives. This step is beneficial for integrating reinforcement learning (RL), as it defines the operational scope within which the RL agent can optimize layout configurations.

In step 120, the system applies a reinforcement learning model to the candidate physical layouts derived from the latent space. The RL model evaluates each layout based on predefined performance metrics such as timing, area, and power. The model iteratively refines the layout by selecting actions that maximize a reward function, which encapsulates design objectives and constraints. This learning-based approach enables the system to autonomously discover high-quality layout solutions that may not be easily attainable through rule-based methods.

In step 125, the system performs parasitic extraction on the candidate physical layouts to estimate resistance-capacitance (RC) values and other layout-dependent electrical characteristics. These extracted values are used to compute a reward signal, which quantifies the quality of each layout in terms of electrical performance. The reward function may incorporate multiple objectives, such as minimizing delay, reducing power consumption, or improving signal integrity. This feedback loop is essential for guiding the RL agent toward optimal design strategies.

In step 130, the computed rewards are passed to the reinforcement learning agent or an auxiliary optimization routine. This feedback is used to update the agent's policy or value function, thereby improving its ability to generate high-quality layouts in future iterations. The reward propagation mechanism ensures that beneficial design decisions are reinforced over time, leading to progressively better layout outcomes.

In step 140, the system updates the layout generation model based on the accumulated learning or re-evaluates the latent space with refined embeddings. This iterative process allows the system to adapt to new design challenges and continuously improve its performance. The updated model can generalize to other standard cells or design contexts, enabling scalable deployment across different semiconductor design tasks. This step ensures that the system evolves with usage, reducing reliance on manual intervention and accelerating the overall design cycle.

FIG. 2 is a simplified schematic showing embodiments using a subsystem 200 (or other subsystem of a larger system). The compression subsystem 223 and its associated processors can be an improved computing subsystem and/or algorithm that performs data reduction, feature selection, or simplification of layout or parasitic extraction data, so that the parasitic capacitance optimization processor 233 has less data to process. The speed improvement arises because the compression subsystem 223 reduces input dimensionality, filters less relevant features, or limits the amount of data passed on, thereby reducing computational load, memory usage, and possibly also reducing model inference time.

The compression subsystem 223 receives input from modeling subsystem 210, which generates or proposes candidate physical layouts or logical layouts; these layouts may come from layout design tools, netlist-to-placement/placement-to-layout steps, or from user inputs. The layout input is denoted layout 205, which contains geometric layout information (layers, shapes, widths, spacings), connectivity (nets), design rules, and optionally process or material metadata.

Within subsystem 200, modeling subsystem 210 may also simulate or approximate parasitic effects or generate features useful for downstream modules. For example, modeling subsystem 210 may compute or extract preliminary features such as net lengths, metal widths, spacing, layer thickness, via count, overlap regions, and adjacency (nearby conductors) information. These features become candidates for compression. Some embodiments may integrate subsystem 200 as part of a larger system that includes layout generation, transistor ordering, PPAC (Performance/Power/Area/Cost) optimization, and final parasitic extraction. In such a system, subsystem 200 acts as an upstream filter, reducing the computational burden on downstream modules, enabling faster iteration cycles in the design verification flow.

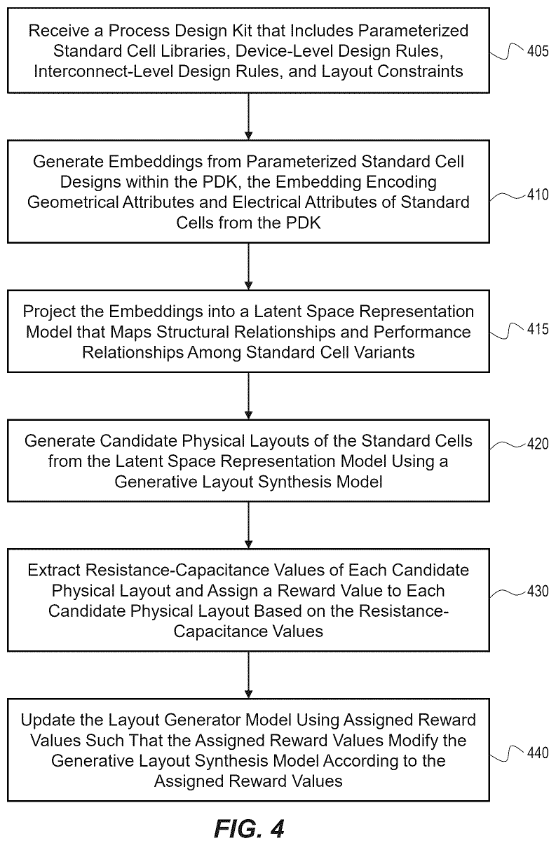

Referring now to FIG. 4, an example process is described, which can be executed by systems herein. In step 405, the system receives a process design kit (PDK) that includes parameterized standard cell libraries, including device-level and interconnect-level design rules, layout constraints, and technology-specific parameters. Having parameters associated with the input is beneficial to have permutations to explore for improved physical design. The process design kit (PDK) can include a collection of predefined parameters and constraints that are important for subsequent steps in the design process. By receiving the PDK, the system is provided with the information that can be used to generate embeddings that will be used in the latent space representation model. The process design kit can include a data file comprising a technology file and a library file.

In step 410, the system generates embeddings from the process design kit (PDK). These embeddings can be vectorized feature embeddings from the parameterized standard cell designs within the PDK, wherein the embeddings encode geometric, electrical, and process variation attributes of standard cells from the PDK. Generating embeddings is beneficial to transform the design data into a format suitable for modelling and analyzing with machine learning engines and neural networks. The embeddings serve as a compact and efficient representation of the design space, enabling the system to navigate the high-dimensional design space more effectively. This transformation into a latent space allows for more effective exploration and manipulation of design parameters to evaluate more candidate designs and options of complex semiconductor layouts. Embeddings herein can be generated using an auto-encoder that acts on a PDK data file as input.

In step 415, the system projects the embeddings into a latent space representation model that maps structural relationships and performance relationships among standard cell variants. This model organizes and structures the design data in a way that facilitates navigation and optimization. The latent space representation serves as a foundation for subsequent optimization steps, allowing the system to explore various design configurations with efficiency. By placing the embeddings in latent space, the system can use structured representation to produce potential design solutions that meet the desired criteria for resistance and capacitance values. In some embodiments, the latent space representation model can map architecture representations of standard cells.

In step 420, the system generates candidate physical layouts of the standard cells from the latent space representation model using a generative layout synthesis model that outputs polygonal geometries conforming to design rule constraints. This step leverages the structured latent space to produce potential design solutions. The generative layout synthesis model uses the embeddings to create candidate physical layouts that have incremental differences in parameter values relative to adjacent parameter values. This process allows for the exploration of a wide range of design possibilities and the identification of configurations that meet the desired criteria for resistance and capacitance values that would otherwise not be possible to do manually. Candidate physical layouts can include three-dimensional layouts using process parameters as inputs.

In step 430, the system extracts resistance-capacitance (RC) parasitic values of each candidate physical layout and assigns a reward value to each candidate physical layout based on the resistance-capacitance parasitic values. This component provides a quantitative measure of the quality of each design. The estimation of resistance-capacitance values is important for assessing the performance of the candidate physical layouts. The reward value serves as feedback for the reinforcement learning model, allowing the system to focus on designs that offer better performance in terms of resistance and capacitance. Parasitic extraction can be executed with conventional techniques or with improved efficiency techniques such as those described in U.S. patent application Ser. No. 19/376,591 titled Method for Parasitic Extraction Using Spatial Localization filed concurrently herewith, the contents of which are incorporated herein by reference in their entirety. Other 3D parasitic extraction tools can be used. In some embodiments, the reward assigned to each candidate physical layout can be based on a combination of estimated resistance/capacitance values and compliance with design rule checks.

In step 440, the system updates the generative layout synthesis model using assigned reward values, allowing the assigned reward values to modify the generative layout synthesis model using a reinforcement learning algorithm according to the assigned reward values. Assigned reward values can be positive or negative. This training technique causes the model to evolve and improve over time. By modifying the generative layout synthesis model based on the reward values, the system can progressively refine design strategies and designs, leading to more efficient and effective semiconductor layouts. This iterative improvement process offers a notable advantage over traditional methods, which may require extensive manual adjustments and longer optimization cycles.

Accordingly, such techniques provide improved processes for semiconductor design, using latent space optimization and reinforcement learning to streamline creation of efficient and compliant standard cell layouts. In various embodiments, the system uses latent space optimization to enhance the efficiency and effectiveness of standard cell layout design processes. The system uses a reinforcement learning (RL) framework to navigate the complex and high-dimensional design space, identifying optimal solutions that adhere to parasitic extraction optimization. The system creates a latent space or latent space representations organizing and evaluating readable parameter variations of the PDK tech file, achieved by passing 3D layout inputs through an auto encoder. Embeddings are placed in a latent space that maps the architecture of a design process, optimizing the layout design. By creating the latent space using all available data, including generated 3D layouts with process parameters as input, design accuracy is improved. The reinforcement learning-based embedding fixing model selects actions from these embeddings by adjusting parameter variations, optimizing the DRC engine's learning curve. Models herein can be trained on readable parameters, enabling the generation of optimized layouts for other cells based on the PDK. The benefit is streamlined creation of efficient and compliant standard cell layouts through latent space optimization and reinforcement learning.

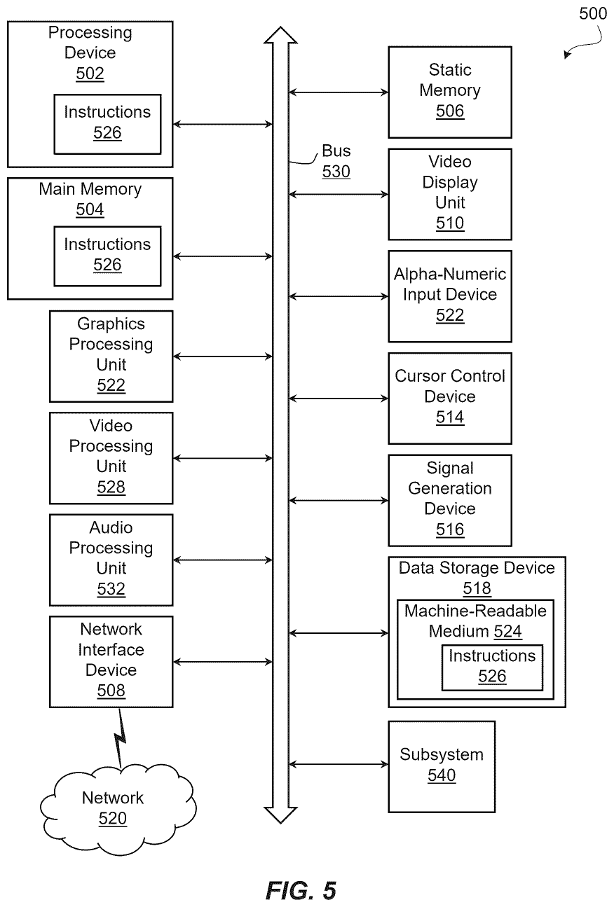

FIG. 5 depicts a representative diagram of an example computer system in which embodiments of the present disclosure may operate.

A storage subsystem of a computer system (such as computer system 500 of FIG. 5) may be used to store the programs and data structures that are used by some or all of the EDA products described herein, and products used for development of cells for the library and for physical and logical design that use the library.

FIG. 5 illustrates an example machine of a computer system 500 within which a set of instructions, for causing the machine to perform any one or more of the methodologies discussed herein, including automated transistor layout design for integrated circuits using latent space modeling, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM), a static memory 506 (e.g., flash memory, static random access memory (SRAM), etc.), and a data storage device 518, which communicate with each other via a bus 530.

Processing device 502 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 may also be one or more special-purpose processing devices such as an application specific integrated circuit (ASIC), a field programmable gate array (FPGA), a digital signal processor (DSP), network processor, or the like. The processing device 502 may be configured to execute instructions 526 for performing the operations and steps described herein.

The computer system 500 may further include a network interface device 508 to communicate over the network 520. The computer system 500 also may include a video display unit 510 (e.g., a liquid crystal display (LCD) or a cathode ray tube (CRT)), an alphanumeric input device 512 (e.g., a keyboard), a cursor control device 514 (e.g., a mouse), a graphics processing unit 522, a signal generation device 516 (e.g., a speaker), graphics processing unit 522, video processing unit 528, and audio processing unit 532.

The data storage device 518 may include a machine-readable storage medium 524 (also known as a non-transitory computer-readable medium) on which is stored one or more sets of instructions 526 or software embodying any one or more of the methodologies or functions described herein. The instructions 526 may also reside, completely or at least partially, within the main memory 504 and/or within the processing device 502 during execution thereof by the computer system 500, the main memory 504 and the processing device 502 also constituting machine-readable storage media.

In some implementations, the instructions 526 include instructions to implement functionality corresponding to the present disclosure. While the machine-readable storage medium 524 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 502 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It may be appreciated that a variety of programming languages may be used to implement the teachings of the disclosure as described herein.

The present disclosure may be provided as a computer program product, or software, which may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It may be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

1. A method for automating semiconductor design, the method comprising:
receiving a process design kit (PDK) that includes parameterized standard cell libraries, device-level design rules, interconnect-level design rules, and layout constraints;
generating, by a processing device, embeddings from parameterized standard cell designs within the PDK, the embeddings being vectorized and encoding geometrical attributes and electrical attributes of standard cells from the PDK;
projecting, by the processing device, the embeddings into a latent space representation model that maps structural relationships and performance relationships among standard cell variants;
generating, by the processing device, candidate physical layouts of the standard cells from the latent space representation model using a generative layout synthesis model that outputs polygonal geometries conforming to design rule constraints;
extracting, by the processing device, resistance-capacitance (RC) parasitic values of each candidate physical layout and assigning a reward value to each candidate physical layout based on the resistance-capacitance (RC) parasitic values; and
updating, by the processing device, the generative layout synthesis model using assigned reward values such that the assigned reward values modify the generative layout synthesis model using a reinforcement learning algorithm according to the assigned reward values.

2. The method of claim 1, wherein updating the generative layout synthesis model includes giving more weight to layout patterns corresponding to comparatively greater reward values.

3. The method of claim 1, further comprising generating second candidate physical layouts using the generative layout synthesis model subsequent to being updated using the latent space representation model and assigned rewards, the second candidate physical layouts having improved design rule checking scores compared to candidate physical layouts.

4. The method of claim 1, wherein extracting resistance-capacitance parasitic values includes using a model that estimates parasitic extraction values by limiting nodes considered to a predetermined distance proximate to given standard cell in the candidate physical layouts.

5. The method of claim 1, wherein the latent space representation model operates within a graph neural network in which the embeddings are used as nodes.

6. The method of claim 1, wherein generating candidate physical layouts from the latent space representation model includes creating an array of candidate physical layouts having incremental differences in parameter values relative to adjacent parameter values.

7. The method of claim 6, wherein parameter variations of the latent space representation model include layer width, layer gap, metal pitch, metal width, and metal material.

8. A system comprising:
a memory storing instructions; and
a processing device, coupled with the memory and configured to execute the instructions, the instructions when executed cause the processing device to:
receive a process design kit (PDK) that includes parameterized standard cell libraries, device-level design rules, interconnect-level design rules, and layout constraints;
generate embeddings, from parameterized standard cell designs within the PDK, that encode geometrical attributes and electrical attributes of standard cells from the PDK;
project the embeddings into a latent space representation model that maps structural relationships and performance relationships among standard cell variants;
generate candidate physical layouts of the standard cells from the latent space representation model using a generative layout synthesis model that outputs polygonal geometries conforming to design rule constraints;
extract resistance-capacitance values of each candidate physical layout and assign a reward value to each candidate physical layout based on the resistance-capacitance values; and
update the generative layout synthesis model using assigned reward values such that the assigned reward values modify the generative layout synthesis model according to the assigned reward values.

9. The system of claim 8, wherein instructions to update the generative layout synthesis model include instructions to give more weight to layout patterns corresponding to comparatively greater reward values.

10. The system of claim 8, wherein the instructions further cause the processing device to:
generate second candidate physical layouts using the generative layout synthesis model subsequent to being updated using the latent space representation model and assigned rewards, the second candidate physical layouts having improved design rule checking scores compared to candidate physical layouts.

11. The system of claim 8, wherein instructions to extract resistance-capacitance values includes instructions to use a model that estimates parasitic extraction values by limiting nodes considered to a predetermined distance proximate to given standard cell in the candidate physical layouts.

12. The system of claim 8, wherein the latent space representation model operates within a graph neural network in which the embeddings are used as nodes.

13. The system of claim 8, wherein instructions to generate candidate physical layouts from the latent space representation model includes instructions to create an array of candidate physical layout having incremental differences in parameter values relative to adjacent parameter values.

14. The system of claim 13, wherein parameter variations of the latent space representation model include layer width, layer gap, metal pitch, metal width, and metal material.

15. A non-transitory computer readable medium comprising stored instructions, which when executed by a processing device, cause the processing device to:
receive a process design kit (PDK) that includes parameterized standard cell libraries, device-level design rules, interconnect-level design rules, and layout constraints;
generate embeddings, from parameterized standard cell designs within the PDK, that encode geometrical attributes and electrical attributes of standard cells from the PDK;
project the embeddings into a latent space representation model that maps structural relationships and performance relationships among standard cell variants;
generate candidate physical layouts of the standard cells from the latent space representation model using a generative layout synthesis model that outputs polygonal geometries conforming to design rule constraints;
extract resistance-capacitance values of each candidate physical layout and assign a reward value to each candidate physical layout based on the resistance-capacitance values; and
update the generative layout synthesis model using assigned reward values such that the assigned reward values modify the generative layout synthesis model according to the assigned reward values.

16. The non-transitory computer readable medium of claim 15, wherein instructions to update the generative layout synthesis model include instructions to give more weight to layout patterns corresponding to comparatively greater reward values.

17. The non-transitory computer readable medium of claim 15, wherein the instructions further cause the processing device to:
generate second candidate physical layouts using the generative layout synthesis model subsequent to being updated using the latent space representation model and assigned rewards, the second candidate physical layouts having improved design rule checking scores compared to candidate physical layouts.

18. The non-transitory computer readable medium of claim 15, wherein instructions to extract resistance-capacitance values includes instructions to use a model that estimates parasitic extraction values by limiting nodes considered to a predetermined distance proximate to given standard cell in the candidate physical layouts.

19. The non-transitory computer readable medium of claim 15, wherein the latent space representation model operates within a graph neural network in which the embeddings are used as nodes.

20. The non-transitory computer readable medium of claim 15, wherein instructions to generate candidate physical layouts from the latent space representation model includes instructions to create an array of candidate physical layout having incremental differences in parameter values relative to adjacent parameter values, and wherein parameter variations of the latent space representation model include layer width, layer gap, metal pitch, metal width, and metal material.
